(19) United States
(12) Patent Application Publication
(10) Pub. No.: US 2025/0203982 A1
(43) Pub. Date: Jun. 19, 2025

(54) POWER SEMICONDUCTOR DEVICE HAVING WITHSTAND VOLTAGE REGION OF VLD STRUCTURE, AND METHOD FOR MANUFACTURING SAME

(71) Applicant: Trinno Technology Co., Ltd., Seoul (KR)

(72) Inventors: Soo Seong KIM, Seoul (KR); Kwang Hoon OH, Seoul (KR); Chongman YUN, Seoul (KR)

(21) Appl. No.: 18/849,533

(22) PCT Filed: Mar. 23, 2023
(86) PCT No.: PCT/KR2023/003837

§ 371 Date: Sep. 23, 2024

(30) Foreign Application Priority Data
Mar. 24, 2022 (KR) 10-2022-0036405

(51) Int. Cl. H10D 62/60; H10D 12/01; H10D 30/01

(52) U.S. Cl. CPC H10D 62/60; H10D 12/031; H10D 30/021

(57) ABSTRACT

Disclosed are a power semiconductor device having a withstand voltage region of a VLD structure, and a method for manufacturing same. The method for manufacturing a power semiconductor device comprises the steps of: deforming an oxide film formed on the top of a first conductive semiconductor substrate into an alternately thick and thin oxide film by using a LOCOS process in a withstand voltage holding region of a power semiconductor device; injecting a second conductive impurity into the semiconductor substrate from the top of the deformed oxide film toward the withstand voltage holding region by using the same concentration of the second conductive impurity and the same injection energy; and diffusing the second conductivity type impurity injected into the semiconductor substrate through the deformed oxide film, thereby forming an inclined doping region of a VLD structure.

### FIELD OF THE INVENTION

The present invention relates to power semiconductor device having a withstand voltage region of VLD (Variation of Lateral Doping) structure and method for manufacturing same.

### BACKGROUND

Power semiconductor devices such as IGBT (Insulated Gate Bipolar Transistor) and MOSFET (Metal-Oxide Semiconductor Field Effect Transistor) are required to support high voltages.

Power semiconductor devices are provided with an active region that functions as an active element and an edge termination region surrounding the active region. The function of the edge termination region is to maintain the high voltage generated on the substrate surface between the active region and the end of the semiconductor device. In order to withstand high voltages, a field limiting ring (FLR) or field plate (FP) structure is widely used in the edge termination region of power semiconductor devices.

However, high-voltage withstanding structures using field limiting rings and so on have the disadvantage of requiring a relatively large area.

In order to overcome these disadvantages, a technique is used to form an gradient doping region 13 having a VLD (Variation of Lateral Doping) structure in the edge termination region so as to be adjacent to the end of the high-concentration p-type base region 12 located in the active region, as shown in FIG. 1.

For reference, reference numeral 11 in FIG. 1 denotes an N-conductivity type semiconductor substrate, 12 denotes a base region, 13 denotes a gradient doped region, 14 denotes a channel stopper region of a higher concentration than the semiconductor substrate, 15 denotes an anode electrode, 16 denotes a channel stopper electrode, 22 denotes a field plate made of metal or polysilicon as in 31 to 35, and 19 and 24 each denotes an insulating layer. The withstand voltage region and the end region indicated separately in FIG. 1 may be collectively referred to as an edge termination region.

Referring to the impurity concentration distribution in the A-A′ region shown in FIG. 1, the gradient doped region 13 as the withstand voltage region is formed as a P conductivity type impurity region having a low concentration compared to the base region 12, more specifically formed as the VLD structure in which the impurity concentration gradually decreases relatively toward the end region of the power semiconductor device.

Since the gradient doped region 13 is formed as the VLD structure, unlike the FLR structure, it has the advantage of being able to withstand a high voltage in a relatively narrow area compared to the FLR structure due to the depletion layer extension into the VLD region.

In order to form the gradient doped region 13 as the VLD structure, as illustrated in FIG. 2, the withstand voltage region in the edge termination region must be divided into several regions (see \textcircled{1} to \textcircled{4} of FIG. 2) and formed as P conductivity type impurity regions with different concentrations and depths.

However, in order to form the gradient doped region 13 with a plurality of impurity regions of different concentrations and depths, different impurity concentrations and different ion implantation energies must be applied to each region, requiring multiple photo-processes, which complicates the process of forming the pressure-maintaining region.

### DETAILED DESCRIPTION OF THE INVENTION

### Technical Objectives

The present invention is intended to provide a power semiconductor device having a withstand voltage region of a VLD structure that can secure stable breakdown voltage characteristics without the complexity of a manufacturing process and without increasing the total area of the device, and a manufacturing method thereof.

The present invention is intended to provide a power semiconductor device and a manufacturing method thereof that can form the gradient doped region of VLD structure in a withstand voltage region by a simple manufacturing process.

Other objectives of the present invention will be easily understood through the following description.

### Technical Solution

According to one aspect of the present invention, there is provided a method for manufacturing a power semiconductor device, including transforming an oxide film on a first conductivity type semiconductor substrate into an alternating thick and thin shaped oxide film in a withstand voltage region, by using LOCOS (LOCal Oxidation of Silicon) process, implanting a second conductivity type impurity at a same concentration and a same implantation energy into the alternating thick and thin shaped oxide film over the withstand voltage region in the semiconductor substrate and forming a gradient doped region of a VLD (Variation of Lateral Doping) structure by diffusing the second conductivity type impurity implanted through the alternating thick and thin shaped oxide film.

The LOCOS process may be performed by depositing a plurality of silicon nitride layers spaced apart from each other on the oxide film in the withstand voltage region, wherein the silicon nitride layers relatively closed to the active region may be deposited so as to have a relatively large width length.

By the LOCOS process, among the thin regions spaced apart in the alternating thick and thin shaped oxide film, the thinner region that is relatively close to the active region may be formed with a relatively smaller thickness.

The second conductivity type impurity implanted at the same concentration and the same implantation energy into the withstand voltage region may be injected into the semiconductor substrate in a relatively greater concentration and relatively deeper in the region relatively close to the active region due to a thickness difference of the alternating thick and thin shaped oxide film.

The gradient doped region may be formed such that the regions closer to the active region have a relatively deeper junction depth.

The silicon nitride layers in the gradient doped region may be deposited to have different width lengths in a first width direction of the power semiconductor device and a body length extending in a second width direction perpendicular to the first width direction. The silicon nitride layers may be formed in a continuous or discontinuous shape in the second width direction.

According to another aspect of the present invention, there is provided a power semiconductor device, including a semiconductor substrate of a first conductivity type, an alternating thick and thin shaped oxide film, formed on the semiconductor substrate in a withstand voltage region by a LOCOS (LOCal Oxidation of Silicon) process, a gradient doped region, contacting a base region located on a boundary side of the active region and formed as a VLD (Variation of Lateral Doping) structure under the alternating thick and thin shaped oxide film in the withstand voltage region, wherein, in order to perform the LOCOS process, a plurality of silicon nitride layers are deposited on the oxide film formed in the withstand voltage region such that the silicon nitride layers relatively close to the active region have a relatively large width length and are spaced apart from each other, wherein the alternating thick and thin shaped oxide film transformed by the LOCOS process is formed such that, among the spaced apart thin regions, the thinner region relatively close to the active region has a relatively smaller thickness.

Other aspects, features, and advantages in addition to the foregoing will become apparent from the following drawings, claims, and detailed description of the invention.

### Effects of the Invention

It is advantageous that the power semiconductor device according to the embodiment of the invention can have withstand voltage region of a VLD structure without the complexity of the manufacturing process and without increasing the overall area of the device.

It is also advantageous that the manufacturing method can form the gradient doped region of VLD structure in the withstand voltage region by a simple manufacturing process.

The effects to be obtained from the invention are not limited to those mentioned above, and other effects not mentioned will be apparent to one having ordinary skill in the art to which the invention belongs from the following description.

### BRIEF DESCRIPTION OF ACCOMPANYING DRAWINGS

FIG. 1 illustrates a cross-sectional view and an impurity concentration distribution of a power semiconductor device in which a gradient doped region is formed in a withstand voltage according to the prior art;

FIG. 2 illustrates a process for forming the gradient doped region in the withstand voltage region according to the prior art;

FIGS. 3 and 4 exemplarily illustrate a process of forming a gradient doped region in a withstand voltage region of a power semiconductor device according to one embodiment of the present invention;

FIG. 5 exemplarily illustrates the morphological characteristics of a deposited silicon nitride layer and a volume-expanded oxide film according to one embodiment of the present invention; and

FIGS. 6 and 7 exemplarily illustrate various shapes of the deposited silicon nitride layer according to each embodiment of the present invention.

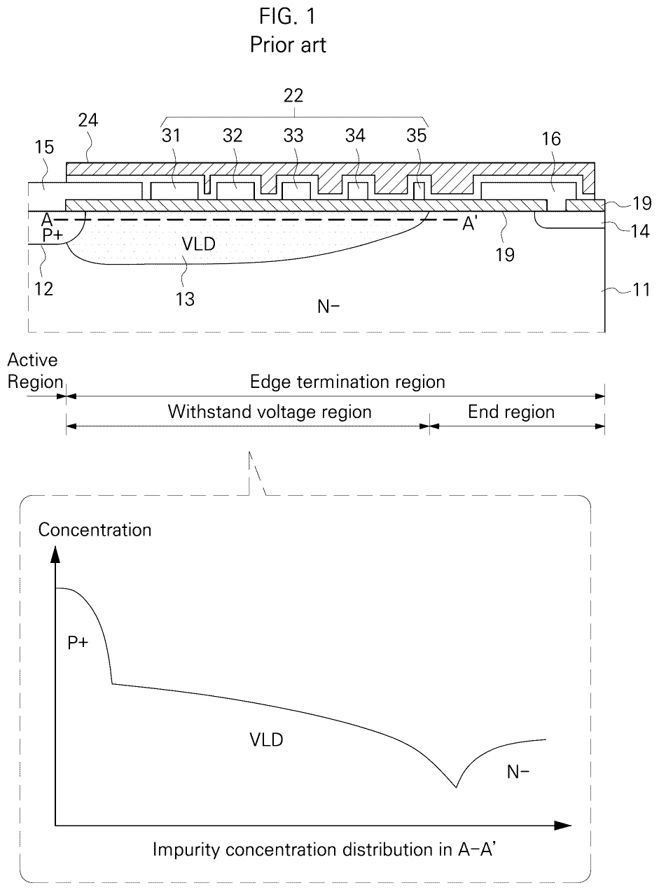

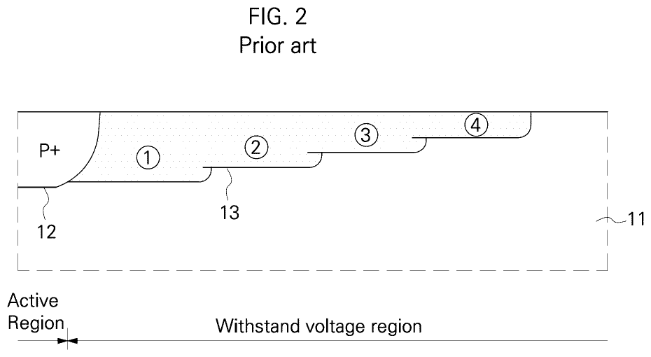

### MODE FOR INVENTION

The invention can be modified in various forms and specific embodiments will be described and shown below. However, the embodiments are not intended to limit the invention, but it should be understood that the invention includes all the modifications, equivalents, and replacements belonging to the concept and the technical scope of the invention. In describing the present invention, if it is determined that a detailed description of a related known technology may obscure the gist of the present invention, the detailed description thereof will be omitted.

Terms such as first, second, etc., may be used to refer to various elements, but, these elements should not be limited due to these terms. These terms will be used to distinguish one element from another element.

The terms used in the following description are intended to merely describe specific embodiments, but not intended to limit the invention. An expression of the singular number includes an expression of the plural number, so long as it is clearly read differently. The terms such as “include” and “have” are intended to indicate that features, numbers, steps, operations, elements, components, or combinations thereof used in the following description exist and it should thus be understood that the possibility of existence or addition of one or more other different features, numbers, steps, operations, elements, components, or combinations thereof is not excluded.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers refer to like elements throughout the specification.

Relative terms, such as “below” or “above” or “upper” or “lower” or “horizontal” or “lateral” or “vertical” may be used herein to describe-one element, layer or region's relationship to another elements, layers or regions as illustrated in the Figures. It will be understood that relative terms are intended to encompass different orientations of the device in addition to the orientation depicted in the Figures.

Embodiments of the present invention will be described in detail below with reference to the accompanying drawings. However, it will be appreciated that the technical idea of the present invention described below may be applied without limitation to various types of power semiconductor devices, such as insulated gate bipolar transistors (IGBTs) and power MOSFETs.

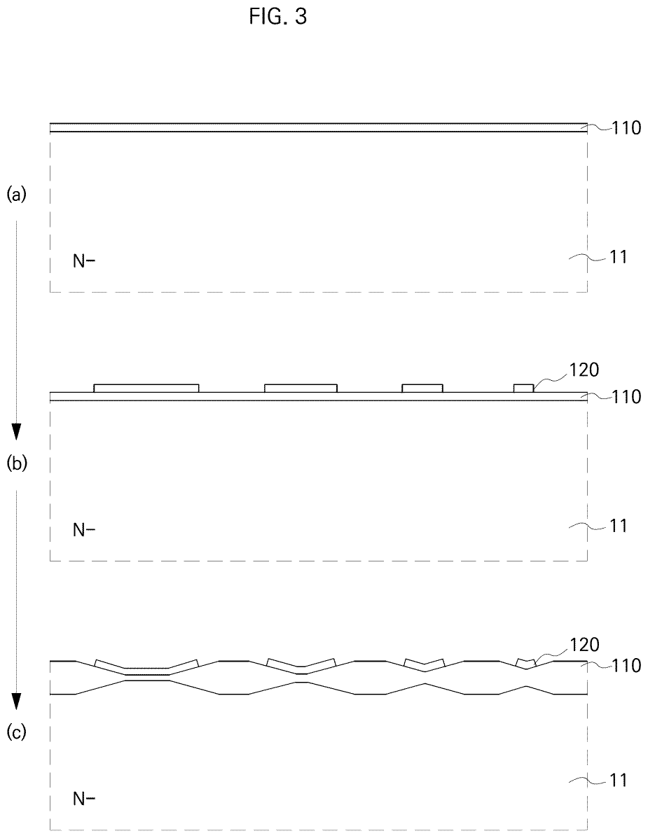

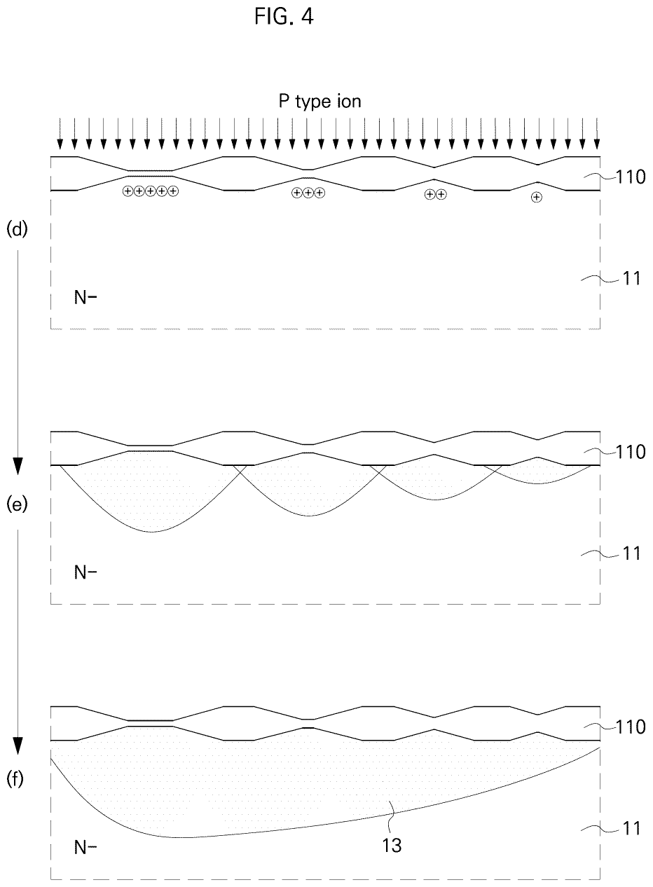

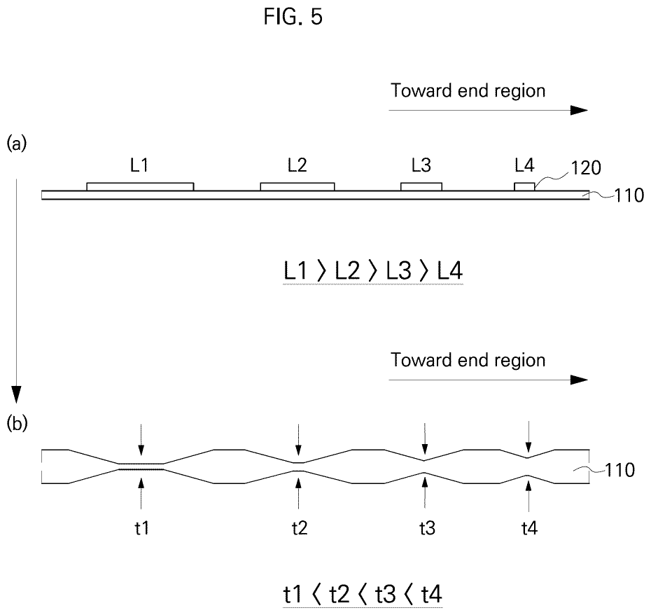

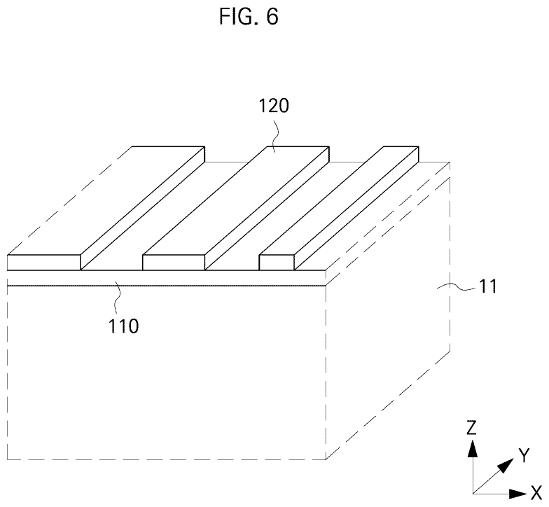

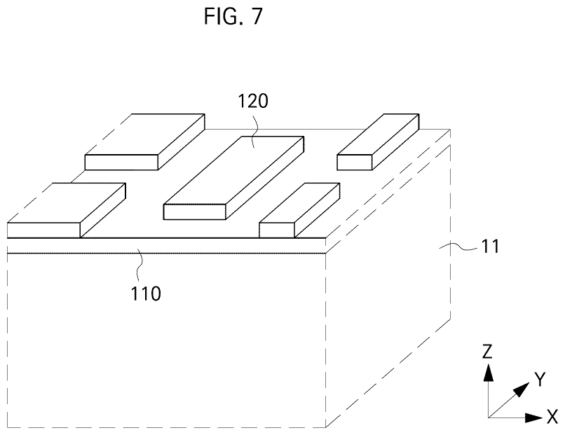

FIGS. 3 and 4 exemplarily illustrate a process of forming a gradient doped region in a withstand voltage region of a power semiconductor device according to one embodiment of the present invention, FIG. 5 exemplarily illustrates the morphological characteristics of a deposited silicon nitride layer and a volume-expanded oxide film according to one embodiment of the present invention, and FIGS. 6 and 7 exemplarily illustrate various shapes of the deposited silicon nitride layer according to each embodiment of the present invention.

The process of forming the gradient doped region 13 in the withstand voltage region of the power semiconductor device will be described with reference to FIGS. 3 and 4. LOCOS (LOCal Oxidation of Silicon) process may be used to form the gradient doped region 13, as described below.

First, an oxide film 110 of SiO₂ is formed on an upper surface of a semiconductor substrate 11 with a predetermined thickness in the withstand voltage region of the power semiconductor device (see (a) of FIG. 3). The oxide film 110 may be formed to be about 1000 Å thick, for example, but its thickness may be changed as needed.

Next, silicon nitride (SiN) layers 120 are deposited on the oxide film 110 so as to be spaced apart from each other in the lateral direction (see (b) of FIG. 3). The silicon nitride layer 120 may be deposited to suppress reaction with oxygen, and may be formed to be, for example, about 1000 Å thick, but its thickness may be changed as needed.

As shown in (a) of FIG. 5, the silicon nitride layers 120 deposited on the oxide film 110 so as to be spaced apart from each other in the lateral direction may be formed to have a relatively large wide width as they get closer to the active region.

Next, the oxide film 110 is grown through a silicon oxidation process (e.g., thermal oxidation) (see (c) of FIG. 3).

At this time, the oxide film 110 of the region blocked by the silicon nitride layer 120 is relatively not grown, and the oxide film 110 of the exposed region grows and expands, so that the oxide film 110 as a whole is transformed into a thick and thin shape with alternating thick and thin regions.

The processes of (a) to (c) of FIG. 3 described above correspond to the LOCOS (LOCal Oxidation of Silicon) process.

Since the size of the blocked regions of the oxide film 110 is determined according to the width of the silicon nitride layer 120 deposited on the oxide film 110, the thicknesses of each of the thin regions in the alternating thick and thin shaped oxide film 110 transformed by the LOCOS process may be different from each other.

That is, as shown in (a) of FIG. 5, if the silicon nitride layer 120 relatively close to the active region is formed to have a relatively wide width and length, as shown in (b) of FIG. 5, among the thin regions that spaced apart in the alternating thick and thin shaped oxide film 110, the thin region relatively close to the active region is formed to have a relatively small thickness.

Next, P conductivity type impurity is ion-implanted at the same concentration and the same implantation energy into the alternating thick and thin shaped oxide film 110 over the entire withstand voltage region of the power semiconductor device. (see (d) of FIG. 4). Before performing the ion-implantation, the silicon nitride layer 120 may be removed.

In this case, the ion-implantation depth of the P conductivity type impurity in each region is determined by the thickness differences of each region of the alternating thick and thin shaped oxide film 110.

That is, since among the thin regions in the alternating thick and thin shaped oxide film 110, the thin region relatively close to the active region is formed with a relatively small thickness, the P conductivity type impurity may be injected relatively deeply in the region relatively close to the active region within the withstand voltage region.

Then, when a diffusion process is performed at a pre-determined temperature (e.g., 1200 degrees) for a pre-determined time (e.g., 300 minutes) for the power semiconductor device, the P conductivity type impurity injected into the withstand voltage region diffuses to form the gradient doped region 13 (see (e) and (f) of FIG. 4).

Since the diffusion process is performed in which a relatively large amount of P conductivity type impurity is injected relatively deeply in a region relatively close to the active region within the withstand voltage region, the gradient doped region 13 is formed in such a shape that the impurity concentration decreases relatively and the junction depth (i.e., the depth of the P conductivity impurity that have been diffused) becomes shallower (the size decreases) as it approaches the end region of the edge termination region.

In FIGS. 6 and 7, the shapes of the silicon nitride layer 120 deposited on the oxide film 110 are exemplified, respectively, in order to transform the oxide film 110 formed in the withstand voltage region into the alternating thick and thin shaped oxide film.

As exemplified in FIG. 6, the silicon nitride layer 120 in the withstand voltage region may be deposited on the oxide film 110 so as to be spaced apart from each other in a striped pattern. Each of the deposited silicon nitride layers 120 may be formed to have a relatively large width length as they get closer to the active region.

By depositing the silicon nitride layers 120 having different width lengths and spaced apart from each other in the X-axis direction, which is a first width direction of the power semiconductor device, and extending in the Y-axis direction, which is a second width direction intersecting the first direction on a plane, a uniformly shaped gradient doped region 13 may be formed in the power semiconductor device.

In addition, as illustrated in FIG. 7, by depositing the silicon nitride layers 120 that have different width lengths and are spaced apart from each other in the X-axis direction of the power semiconductor device and are also spaced apart from each other in the Y-axis direction, the gradient doped region 13 that is non-uniform in both the X-axis direction and the Y-axis direction.

Here, the region blocked by the silicon nitride layer 120 is the region where the growth of the oxide film 110 is suppressed, and thus, P conductivity type impurity may be relatively easily injected.

In comparison, the exposed oxide film 110 region grows to expand in volume, the amount of impurity injected under the expanded region of the oxide film 110 becomes less, and the impurity injected into the periphery diffuse to form the gradient doped region 13, resulting in a relatively shallow junction depth and low impurity concentration. In this case, an imbalance also occurs in the expansion of the depletion layer by the gradient doped region 13, but the region having a relatively shallow junction depth and a low concentration in the gradient doped region 13 has the advantage that the region where the depletion layer can be expanded can be relatively large, and consequently, a relatively high reverse voltage can be supported.

Although the present invention has been described above with reference to embodiments thereof, it will be understood by those skilled in the art that various modifications and changes may be made to the present invention without departing from the spirit and scope of the present invention as set forth in the claims below.

What is claimed is:

1. A method for manufacturing a power semiconductor device, comprising:
transforming an oxide film on a first conductivity type semiconductor substrate into an alternating thick and thin shaped oxide film in a withstand voltage region, by using LOCOS (LOCal Oxidation of Silicon) process;
implanting a second conductivity type impurity at a same concentration and a same implantation energy into the alternating thick and thin shaped oxide film over the withstand voltage region in the semiconductor substrate; and
forming a gradient doped region of a VLD (Variation of Lateral Doping) structure by diffusing the second conductivity type impurity implanted through the alternating thick and thin shaped oxide film.

2. The method of claim 1, wherein the LOCOS process is performed by depositing a plurality of silicon nitride layers spaced apart from each other on the oxide film in the withstand voltage region,
wherein the silicon nitride layers relatively closed to the active region are deposited so as to have a relatively large width length.

3. The method of claim 2, wherein by the LOCOS process, among the thin regions spaced apart in the alternating thick and thin shaped oxide film, the thinner region that is relatively close to the active region is formed with a relatively smaller thickness.

4. The method of claim 3, wherein the second conductivity type impurity implanted at the same concentration and the same implantation energy into the withstand voltage region is injected into the semiconductor substrate in a relatively greater concentration and relatively deeper in the region relatively close to the active region due to a thickness difference of the alternating thick and thin shaped oxide film.

5. The method of claim 4, wherein the gradient doped region is formed such that the regions closer to the active region have a relatively deeper junction depth.

6. The method of claim 2, wherein the silicon nitride layers in the gradient doped region is deposited to have different width lengths in a first width direction of the power semiconductor device and a body length extending in a second width direction perpendicular to the first width direction.

7. The method of claim 6, wherein the silicon nitride layers are formed in a continuous or discontinuous shape in the second width direction.

8. A power semiconductor device, comprising:
a semiconductor substrate of a first conductivity type;
an alternating thick and thin shaped oxide film, formed on the semiconductor substrate in a withstand voltage region by a LOCOS (LOCal Oxidation of Silicon) process;
a gradient doped region, contacting a base region located on a boundary side of the active region and formed as a VLD (Variation of Lateral Doping) structure under the alternating thick and thin shaped oxide film in the withstand voltage region,
wherein, in order to perform the LOCOS process, a plurality of silicon nitride layers are deposited on the oxide film formed in the withstand voltage region such that the silicon nitride layers relatively close to the active region have a relatively large width length and are spaced apart from each other,
wherein the alternating thick and thin shaped oxide film transformed by the LOCOS process is formed such that, among the spaced apart thin regions, the thinner region relatively close to the active region has a relatively smaller thickness.
